(19) United States
(12) Patent Application Publication
(10) Pub. No.: US 2014/0306722 A1
(43) Pub. Date: Oct. 16, 2014

(54) CIRCUIT FOR MEASURING ELECTROSTATIC CAPACITY USING A CURRENT SOURCE TECHNIQUE AND CIRCUIT FOR MEASURING ELECTROSTATIC CAPACITY USING SAME

(71) Applicants: Tae Whan Kim, Seoul (KR); Su Hyeong Park, Gyeongju-si (KR)

(72) Inventors: Tae Whan Kim, Seoul (KR); Su Hyeong Park, Gyeongju-si (KR)

(73) Assignee: Intellectual Discovery Co., Ltd., Seoul (KR)

(21) Appl. No.: 14/241,862

(22) PCT Filed: Aug. 26, 2011
(86) PCT No.: PCT/KR2011/006324

§ 371 Date: Jun. 3, 2014

(51) Int. Cl. G01R 31/02

(52) U.S. Cl. CPC G01R 31/028
USPC 324/658

(57) ABSTRACT

According to the present invention, a circuit for measuring electrostatic capacity using a current source technique, which includes an external capacitor and at least one pad capacitor, comprises: a charging/discharging unit charging and discharging the at least one pad capacitor using a constant current source; and a charge sharing switching unit performing a control to share a charge between the charged or discharged pad capacitor and the external capacitor. By charging/discharging the pad capacitor using a current source and sharing the charge between the pad capacitor and the external capacitor, the advantages of a technique for using a voltage source and a conventional technique for using a current source may be combined, and their drawbacks may each be remedied.

### CROSS-REFERENCE TO RELATED APPLICATION

This application is the National Stage Entry of International Application No. PCT/KR2011/006324, filed on Aug. 26, 2011, which is hereby incorporated by reference for all purposes as if fully set forth herein.

### BACKGROUND

1. Field

Example embodiments of the present invention relate to a circuit for measuring electrostatic capacity, and more specifically to a circuit for measuring electrostatic capacity using a current source.

2. Discussion of the Background

A touch sensor is a type of an input apparatus. A touch sensor technique is a technique providing information about touched positions by detecting whether an object touches a touch sensor or not through a microprocessor and peripheral circuits when the object touches a transparent or a non-transparent touch sensor.

In a touch screen panel, touch sensors are arranged on a substrate. The touch screen panel is characterized that it provides information about touched positions on the touch screen panel when an object touches the substrate by utilizing such the touch sensor technique.

The object detected by the touch screen panel may be a human body, a pen, or other object according to a detection method used for the touch screen panel. When the touch screen panel is used as combined with an image display apparatus, in order to make displayed information visible, the touch screen panel should be manufactured by using transparent substrates or films, or should be configured around the image display apparatus.

Generally, a touch screen panel is classified into a resistive film type, an electrostatic capacity type, an infrared type, an ultrasonic type, etc. The resistive film type and the ultrasonic type are usually used for a medium-sized or small-sized panel. Also, the infrared type and the ultrasonic type are usually used for a large-sized panel. For both the resistive film type and the electrostatic capacity type, indium tin oxide (ITO), a transparent conductive film, is used as a pad detecting whether an object touches the pad or not and is arranged on the image is display apparatus. For the infrared type and the ultrasonic type, a pad detecting whether an object touches or not is arranged on edges of the image display apparatus and detects positional information.

In the case of the resistive film type widely used for medium-sized and small-sized panels, there are advantages of low manufacturing costs and high detection efficiency due to a simple structure. However, there are disadvantages of low durability due to direct contact pressures of objects and low optical transmittance due to layered structures of multiple transparent conductive films.

On the other hand, as compared with the resistive film type, the electrostatic capacity type has disadvantages of a complex structure, high manufacturing costs, and low detection efficiency due to noise generation. However, it has advantages of high optical transmittance and high durability due to the contactless operation manner.

In the electrostatic capacity type, a value of electrostatic capacity of a touch sensor is none or very small when a human body does not contact a panel. Also, a value of electrostatic capacity corresponding to a touched area size is detected when a human body touches a panel.

A shape of the touch pad detecting electrostatic capacity may be configured variously as follows. That is, it may have cells located in each target positions, or it may have a is shape having variable contact areas according to position, or it may have an array shape in which uniform wires are intersected.

For various arrangements of electrodes, conventional circuits for measuring electrostatic capacity may generally be classified into a type of charging and discharging using a voltage source and a type of charging and discharging using a current source.

FIG. 1 illustrates a conventional circuit for measuring electrostatic capacity of a type of charging and discharging using a voltage source.

Referring to FIG. 1, in case of the type using a voltage source, a separate external capacitor (Cₑₓₜ) is prepared in an external circuit connected to a touch pad. Initially, a pad capacitor (C_{pad}) of the touch pad is charged, and then the pad capacitor (C_{pad}) is discharged by performing a charge sharing between the pad capacitor and the external capacitor through a switching controlled by a clock pulse (Clk). The above-described procedure is repeated, and a decrease of a voltage of the external capacitor according to the repetition number is detected. Since the decrease of the voltage varies according to an electrostatic capacity of the touch pad, a resolution according to a size of an area touched by a human body can be enhanced.

FIG. 2 illustrates a conventional circuit for measuring electrostatic capacity of a type of charging and discharging using a current source, and FIG. 3 is a timing diagram illustrating a charging period and a discharging period of the conventional circuit for measuring is electrostatic capacity of a type of charging and discharging using a current source.

Referring to FIG. 2, in order to measure an electrostatic capacity formed between a touch pad and a human body, after the pad capacitor is completely discharged by grounding an electrode of a touch pad to a ground (GND), a time required for charging an electrostatic capacity component of the pad capacitor (C_{pad}) to a reference voltage (V_{ref}), which is an electrostatic capacity generated from a static current source connected to V_{DD} by the electrode of the touch pad and a human body, is measured by a timer using a high-speed clock. Then, a value of the electrostatic capacity is measured by using a value of the timer.

At this time, a comparator COMP performs a function of comparing the reference voltage (V_{ref}) with a voltage of the touch pad (V_{pad}), which changes according to a change of the electrostatic capacity component (C_{pad}) formed in the electrode of the touch pad. Referring to FIGS. 2 and 3, a signal OUT, which is a comparison result of the comparator, is used as a signal controlling a switch SW used for discharging the electrode when the OUT signal is high, and a high-speed clock is used as a control signal for the timer measuring a time (tchar) when the OUT signal is low.

In such the conventional type using a current source, due to limitation of the high-speed clock used for measuring electrostatic capacity, a current source providing a very small amount of current is used in order to complete the discharging in a very short time (tdis) is when the discharging is performed and in order to obtain an enough timer value when the charging is performed. At this time, the minute current provided from the current source is usually ranged from several hundreds of pA to several μA. As shown in FIG. 3, the charged voltage(tchar) increases linearly since the charging is performed using a static current source.

In case of the type using a current source, when the pad capacitor (C_{pad}) is charged or discharged, a value of electrostatic capacity may be measured using linear relations about an amount of current, a voltage change, a charging/discharging time, and a size of a capacitor. For example, when a capacitance of the pad capacitor changes for a specific amount of current, a time required for a voltage of the pad capacitor to be changed into a specific value may be measured. Otherwise, a voltage charged or discharged during a specific time period may be measured.

For both the type using a current source and the type using a voltage source, a counter may be used for measuring time, and an analog-to-digital converter (ADC) may be used for measuring changed voltage.

In the case of the type of charging/discharging using a voltage source of FIG. 1, if the pad capacitor and the external capacitor are short-circuited, their voltages become identical due to charge sharing. After disconnecting the pad capacitor and the external capacitor, charging and discharging on the pad capacitor are performed repetitively so that the voltage of the external capacitor changes. A voltage change due to the above-described procedure may be represented as a below equation 1.

$${Q}_{pad} = {C}_{pad} {V}_{HH} \\ {Q}_{ext} = {C}_{ext} {V}_{ext} \\ \begin{matrix}{Q}_{total} = {C}_{total} {V}^{*} = ( {C}_{pad} + {C}_{ext} ) {V}^{*} \\ = ( {C}_{pad} {V}_{HH} + {C}_{ext} {V}_{ext} )\end{matrix} \\ \begin{matrix}{V}^{*} = \frac{{C}_{pad} {V}_{HH} + {C}_{ext} {V}_{ext}}{{C}_{pad} + {C}_{ext}} {C}_{ext} = {kC}_{pad} \\ = \frac{{C}_{pad} {V}_{HH} + {kC}_{pad} {V}_{ext}}{{C}_{pad} + {kC}_{pad}} = \frac{{V}_{pad} + k {V}_{ext}}{1 + k}\end{matrix} \\ {V}^{*} = \frac{k}{1 + k} {V}_{ext} + \frac{{V}_{HH}}{1 + k} \qquad Equation 1$$

A charge quantity of the touch pad electrode (Q_{pad}), before the short-circuiting, may be represented as a multiplication of a capacitance of the touch pad electrode (C_{pad}) by a charged voltage of the pad capacitor (V_{HH}; V_{HH}=V_{pad}). At this time, the touch pad electrode is always charged to V_{HH}. Similarly, a charge quantity of the external capacitor (Qₑₓₜ) may be represented as a multiplication of a capacitance of the external capacitor (Cₑₓₜ) by a charged voltage of the external capacitor (Vₑₓₜ).

When the pad capacitor and the external capacitor are short-circuited, their voltages become identical. Thus, a total charge quantity (Qₜₒₜₐₗ) may be represented as a multiplication of a sum of the two capacitances by a voltage (V*) which is a voltage after the short-circuiting. Therefore, V* becomes (C_{pad}*V_{HH}+Cₑₓₜ*Vₑₓₜ)/(C_{pad}+Cₑₓₜ). If Cₑₓₜ/C_{pad} is substituted with k, V*=(k/(1+k))*Vₑₓₜ+(1/(1+k)*V_{HH}.

When the above-procedure is performed repetitively, a general term of a series can be derived according to a mathematical induction method.

V* can be substituted with a Vₑₓₜ₍ₙ₎ when the above procedure is repeated n times, and Vₑₓₜ may be substituted with a Vₑₓₜ₍ₙ₋₁₎ which is a voltage after (n−1) times of repetitions. Thus, a below equation 2 may be derived.

$${V}_{ext ( n )} = \frac{k}{1 + k} {V}_{ext ( n - 1 )} + \frac{{V}_{HH}}{1 + k} \qquad Equation 2$$

The above equation 2 may be changed into a geometric progression as shown in a below equation 3. Since an initial voltage is 0, a general term of Vₑₓₜ₍ₙ₎ may be represented in to exponential representation.

$$[ {V}_{ext ( n )} = {V}_{HH} ] = \frac{k}{1 + k} [ {V}_{ext ( n - 1 )} - {V}_{HH} ] \\ [ {V}_{ext ( n )} - {V}_{HH} ] = [ {V}_{ext ( 0 )} - {V}_{HH} ] {( \frac{k}{1 + k} )}^{n} {V}_{ext ( 0 )} = 0 \\ {V}_{ext ( n )} = ( - {V}_{HH} ) {( \frac{k}{1 + k} )}^{n} + {V}_{load} \\ {V}_{ext ( n )} = {V}_{HH} [ 1 - {( \frac{k}{1 + k} )}^{n} ] ( k = \frac{{C}_{ext}}{{C}_{pad}} ) \\ {V}_{ext ( n )} = {V}_{HH} [ 1 - {( \frac{{C}_{ext}}{{C}_{pad} + {C}_{ext}} )}^{n} ] \qquad Equation 3$$

If the charge sharing and the charging are repeated n times, a voltage of the external capacitor (Cₑₓₜ) may be represented as Vₑₓₜ₍ₙ₎=V_{HH}*(1−(Cₑₓₜ/(C_{pad}+Cₑₓₜ))ⁿ) which is a formula having exponential representation according to a ratio between the external capacitance and the pad capacitance and the number of repetitions. In this case, since the switching for charge sharing and the switching for charging are controlled by a fixed clock pulse, an execution time for each repetition may be identical to a period of clock (tclk). Therefore, a change of voltage according to time may be derived as an exponential function.

In the case of such the conventional type using a voltage source, since a voltage increases exponentially as n increases, the electrostatic capacity of the touch pad electrode which changes when a portion of a human body touches the touch pad electrode is not proportional to the voltage change. Thus, when the value of the electrostatic capacity is obtained by measuring voltage change during a specific operation period or is obtained by measuring a time required for reaching a reference voltage by using a counter, an additional logarithmic function computation is necessary to detect whether a touch is generated or not, and a separate memory storing a table is for the logarithmic function computation is demanded additionally.

Also, according to the exponential function, a voltage difference between large values of C_{pad} has a disadvantage of small selection ratio as compared with a voltage difference between small values of C_{pad}. Also, since an increase range of the voltage becomes smaller as the repetition number increases, it has a disadvantage that charging efficiency decreases and the operation time needed for measuring increases according to elapsed time.

According to a design based on the above-described equations, the operation that C_{pad} is charged to V_{HH}; charge sharing between C_{pad} and discharged Cₑₓₜ is performed; C_{pad} is charged again; and then Cₑₓₜ is charged by C_{pad} may be repeated. On the contrary, the operation that C_{pad} is discharged; charge sharing between C_{pad} and Cₑₓₜ charged to V_{HH} is performed; and the C_{pad} is discharged again may be repeated. Generally, when a circuit for charging/discharging using a voltage source is designed, it is designed as focusing on only one of charging operation and discharging operation and it is switched by control of clock pulses. Therefore, it may have large power consumption.

Meanwhile, in the case of the conventional type of charging/discharging using a current source, formulas representing linear relations between a current (I) flowing through a capacitor (C), a time for charging/discharging (Δt), and a voltage change (ΔV) are used. Due to characteristics of proportional increase in charging operation and proportional decrease in is discharging operation, it has advantages of easiness of measuring.

$$Δ V = \frac{I Δ t}{C} \qquad Equation 4$$

As shown in the above equation 4, an electrostatic capacity may be derived by measuring a voltage change during a specific time period when a static current flows through a capacitor. Since the capacitance changes when a human body contacts an electrode, the amount of the voltage change is inversely proportional to the capacitance.

$$Δ t = \frac{C Δ V}{I} \qquad Equation 5$$

Also, as shown in the above equation 5, an electrostatic capacity may be derived by measuring a time consumed until the amount of voltage change reaches a specific value. Similarly, since the capacitance changes when a human body contacts an electrode, the time required for charging or discharging is inversely proportional to the capacitance.

However, since an electrostatic capacity formed between the electrode and a human body is very small, that is, several pF to several tens of pF, when a voltage is measured by using the conventional techniques, the amount of voltage change in a unit time is very large and the voltage is shortly charged to a maximum level so that it is difficult to be measured. Also, when a time required for the voltage change is measured, the time for charging/discharging is very short so that a timer using very high-speed clock becomes necessary.

Generally, a charging or discharging current used for measuring electrostatic capacity is very small, several hundreds of pA to several μA. If amount of flowing current is made smaller in order to make measurement of electrostatic capacity easier, a signal-to-noise ratio (SNR), due to a leakage current due to parasitic resistances existing in semiconductor elements, a contact resistance between a measuring circuit and a touch screen panel, and external environments, increases so that a detection rate decreases.

If a two-way circuit which performs charging operation and discharging operation alternately is used for charging and discharging C_{pad}, the disadvantages due to measurement based on a single charging or discharging operation can be resolved. However, since a cycle time of charging and discharging operations is short, a time is measured using n to cycles of operations. In this case, there is a disadvantage that a separate counter should be prepared to count cycle repetition number in addition to a counter measuring a time required for performing n cycles and a microprocessor controls operations by using the counter.

### SUMMARY

The conventional measuring circuit of charging and discharging type using a voltage source has an advantage that charging or discharging is performed using the voltage source, charge sharing is performed by switching, and voltage change or time change can indirectly be measured by an external capacitor, in the measuring circuit, having a larger capacitance than a capacitance of touch pad electrode. However, since the voltage changes exponentially, efficiency of charging or discharging degrades as time elapses and a selection ratio of a measurement value is non-linear.

The conventional measuring circuit of charging and discharging type using a current source has an advantage that measurement and computation are easy since voltage change increases or decreases proportionately to time when the charging and discharging are performed using the current source. On the contrary, there are disadvantages that a current used for measuring should become very small and a signal-to-noise ratio (SNR) increases accordingly.

There, the first objective of the present invention is to provide a circuit for measuring electrostatic capacity using a current source, which can combine advantages of the conventional current source type and the conventional voltage source type and supplement disadvantages of them.

Also, the second objective of the present invention is to provide a current source type method for measuring electrostatic capacity using the above circuit for measuring electrostatic capacity.

A circuit for measuring electrostatic capacity using a current source, including an external capacitor and at least one pad capacitor, according to an aspect of the present invention for achieving the first objective of the present invention, may comprise a charging/discharging part for charging or discharging the at least one pad capacitor by using the current source; and a charge sharing switching part for controlling charge sharing between the charged or discharged external capacitor and at least one pad capacitor.

Also, a method for measuring electrostatic capacity using a current source, including an external capacitor and at least one pad capacitor, according to another aspect of the present invention for achieving the second objective of the present invention, may comprise charging or discharging the at least one pad capacitor by using a static current source; and performing charge sharing between the charged or discharged at least one pad capacitor and the external capacitor.

As described above, the circuit for measuring electrostatic capacity using a current source and the method for measuring electrostatic capacity using a current source may combine advantages of the conventional methods using a voltage source and a current source and supplement disadvantages of them by charging and discharging the pad capacitor (C_{pad}) by using the current source and performing charge sharing between the pad capacitor and the external capacitor (Cₑₓₜ).

The pad capacitor (Cpad) is charged or discharged by using a current source, and charges of the pad capacitor (Cpad) and the external capacitor (Cext) are shared. Thus, although a voltage of the external capacitor changes as time elapses, a linear relation may be maintained and design parameters may be simplified.

Also, even when a large current is used, the circuit and the method according to example embodiments of the present invention have a good margin of measurement since a time for a single charging or discharging period is long. Also, they may be applied to both a method for measuring a time required for being charged to a reference voltage by using a timer and a method for measuring an amount of voltage change to the reference voltage.

Also, the method and the circuit according to example embodiments of the present invention can use multiple measurement modes, and so a time and degree of precision for measurement on a human body touch may be controlled variously by adjusting an amount of current (I) and a capacitance of the external capacitor (Cₑₓₜ). In this case, instead of switching by using a microprocessor for such the operation, a feedback logic circuit may be used to control switching actively according to voltages of the pad capacitor (C_{pad}) and the external capacitor (Cₑₓₜ) so that the operation speed can be increased and the implementation cost can be reduced.

Also, the multiple modes can be used by changing the amount of charging/discharging current (I) and the capacitance of the external capacitor (Cₑₓₜ).

Also, since the large amount of current may be used, reduction of signal-to-noise ratio (SNR) to leakage current of the circuit can be prevented. In addition, although the large amount of current is used, a number of operations for charging or discharging the external capacitor (Cₑₓₜ) are repeated, so that margin of measurement becomes large and computation and design of the circuit become simplified according to the linear relation.

The circuit and method according to example embodiments of the present invention may be applied to a circuit for measuring electrostatic capacity of an electrostatic capacity type touch screen panel. Also, they may be applied to embedded or external-type touch sensor and touch screen panel, and an image display apparatus including them. Also, they may be applied to high-precision electrostatic capacity type touch sensor and touch screen panel using a small current, and high-speed electrostatic capacity type touch sensor and touch screen panel using a large current.

### BRIEF DESCRIPTION OF THE DRAWINGS

FIG. 1 illustrates a conventional circuit for measuring electrostatic capacity of a type of charging and discharging using a voltage source;

FIG. 2 illustrates a conventional circuit for measuring electrostatic capacity of a type of charging and discharging using a current source;

FIG. 3 is a timing diagram illustrating a charging period and a discharging period of the conventional circuit for measuring electrostatic capacity of a type of charging and discharging using a current source;

FIG. 4 is a circuit diagram illustrating a circuit for measuring electrostatic capacity using a current source based on current charging and charge sharing method according to the present invention;

FIG. 5 illustrates a circuit for controlling charging operations of a charging part of FIG. 4;

FIG. 6 is a circuit diagram illustrating an example of the charging part of FIG. 4;

FIG. 7 is a circuit diagram illustrating an example of a charge sharing switching part of FIG. 4;

FIG. 8 illustrates results of simulation on the circuit for measuring electrostatic capacity using a current source of FIG. 4;

FIG. 9 is a circuit diagram illustrating a circuit for measuring electrostatic capacity using a current source based on current charging and charge sharing method according to another example embodiment of the present invention;

FIG. 10 illustrates a circuit for controlling discharging operations of a discharging part of FIG. 4;

FIG. 11 is a circuit diagram illustrating an example of the discharging part of FIG. 9;

FIG. 12 is a circuit diagram illustrating an example of a charge sharing switching part of FIG. 9;

FIG. 13 illustrates results of simulation on the circuit for measuring electrostatic capacity using a current source of FIG. 9;

FIG. 14 is a circuit diagram illustrating a circuit for measuring electrostatic capacity using a current source based on current charging/discharging and charge sharing method according to other example embodiment of the present invention;

FIG. 15 illustrates an example of a reference voltage generating circuit for generating reference voltages used for a circuit for measuring electrostatic capacity using a current source;

FIG. 16 illustrates an example of a circuit for comparator used for a circuit for measuring electrostatic capacity using a current source;

FIG. 17 illustrates a charging/discharging control circuit for controlling charging and discharging operations of a charging part and a discharging part of FIG. 14;

FIG. 18 is a circuit diagram illustrating an example of a charging/discharging static current source circuit of the charging/discharging part (the charging part and the discharging part);

FIG. 19 is a circuit diagram illustrating an example of a charging/discharging switch for charging/discharging part (the charging part and the discharging part);

FIG. 20 is a circuit diagram illustrating an example of a charge sharing switching part of FIG. 14;

FIG. 21 illustrates results of simulation on the circuit for measuring electrostatic capacity of FIG. 14;

FIGS. 22 and 23 represent output waveforms of a comparing part and a charging/discharging control circuit in connection with the results of FIG. 21;

FIGS. 24 and 25 illustrate an example of a static current source circuit for changing a charging/discharging current according to a mode;

FIG. 26 illustrates an example of a circuit for changing a capacitance of the external capacitor (Cₑₓₜ);

FIG. 27 is a graph illustrating change of Cₑₓₜ according to change of C_{pad} in a circuit operating in a small-current low-speed mode; and

FIG. 28 is a graph illustrating change of Cₑₓₜ according to change of C_{pad} in a circuit operating in a large-current high-speed mode.

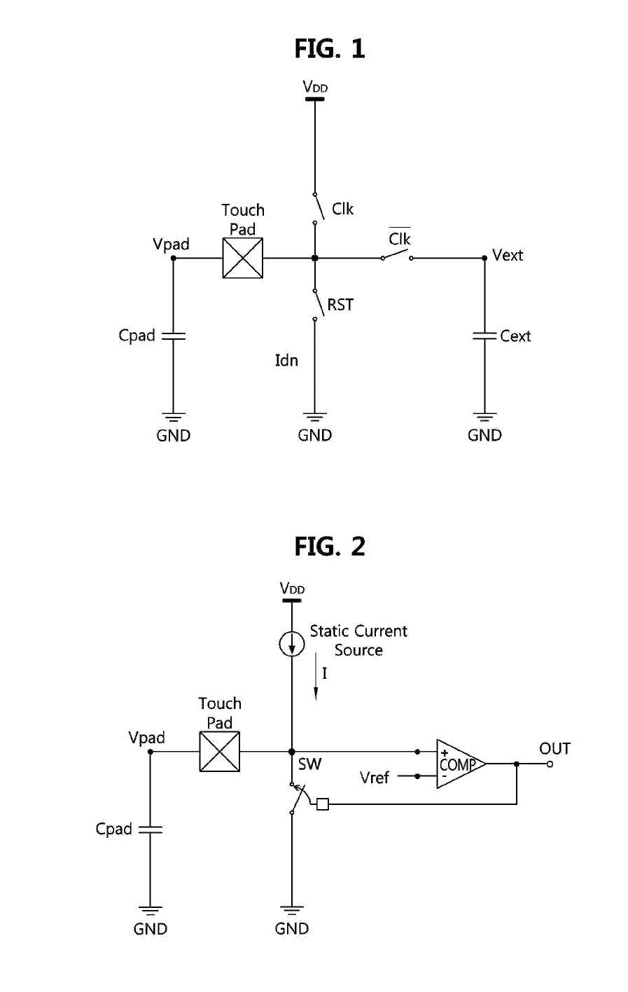

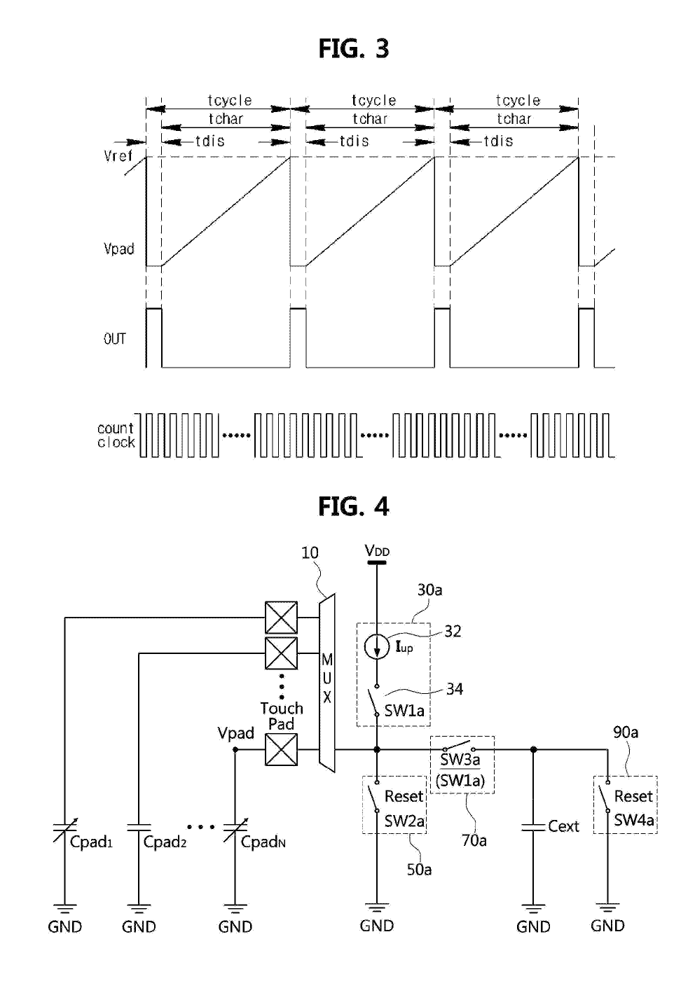

### DETAILED DESCRIPTION OF THE ILLUSTRATED EMBODIMENTS

Example embodiments of the present invention are disclosed herein. However, specific structural and functional detail disclosed herein are merely representative for purposes of describing example embodiments of the present invention, however, example embodiments of the present invention may be embodied in many alternate forms and should not be construed as limited to example embodiments of the present invention set forth herein. Accordingly, while tie invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that when an element is referred to as being “on” or “below” another element, it can be directly on another element or intervening elements may be present.

It will be understood that, although the terms first, second, A, B, etc. may be used herein to describe various elements, these elements should not be limited by these terms. These terms are only used to distinguish one element from another. For example, a first element could be termed a second element, and similarly, a second element could be termed a first element, without departing from the scope of the present invention. As used here, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of the invention. As used herein, the singular forms are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present invention will be described in detail with reference to the appended drawings. In the following description, for easy understanding, like numbers refer to like elements throughout the description of the figures regardless of number of the figures.

In case of a circuit for measuring electrostatic capacity using a current source, when charging and discharging are performed for a pad capacitor (C_{pad}) by using a static current source, a time (Δt) required for a voltage change to a reference voltage (V_{HH}) is linear according to an equation

$$Δ t = \frac{C Δ V}{I} .$$

An amount of voltage change (ΔV) is constant in the conventional charging/discharging. However, in a method for measuring electrostatic capacity using a current source according to an example embodiment of the present invention, since a charge sharing between an external capacitor (Cₑₓₜ) and the pad capacitor (C_{pad}) occurs after the voltage of the pad capacitor is charged to V_{HH}, an amount of voltage change (ΔV) when the pad capacitor (C_{pad}) is charged again to V_{HH} may be variable. Also, since charging and discharging on the pad capacitor (C_{pad}) are performed linearly, a time (Δt) required for the charging and is discharging is variable proportionally to the voltage change (ΔV). A charging period may be explained by using equations as follows.

According to the repetition number of charging (n), n^{th} voltage (Vₑₓₜ₍ₙ₎) of the external capacitor may be represented as shown in the following equation 6. Also, a voltage of an electrode (V_{pad(n)}) is identical to the Vₑₓₜ₍ₙ₎ due to charge sharing.

$${V}_{pad ( n )} = {V}_{ext ( n )} = {V}_{HH} [ 1 - {( \frac{{C}_{ext}}{{C}_{pad} + {C}_{ext}} )}^{n} ] \qquad Equation 6$$

Since a time required for charge sharing is very short, it may be negligible. A time required for the n^{th} operation may be identical to a time required for charging the pad capacitor (C_{pad}) for the n^{th} repetition. Thus, the time may be represented as a below equation 7.

$$\begin{matrix}Δ {t}_{( n )} = \frac{{C}_{pad} Δ {V}_{pad ( n )}}{I} = \frac{{C}_{pad}}{I} ( {V}_{HH} - {V}_{pad ( n - 1 )} ) \\ = \frac{{C}_{pad}}{I} ( {V}_{HH} - {V}_{HH} [ 1 - {( \frac{{C}_{ext}}{{C}_{pad} + {C}_{ext}} )}^{n - 1} ] ) \\ = \frac{{C}_{pad} {V}_{HH}}{I} {( \frac{{C}_{ext}}{{C}_{pad} + {C}_{ext}} )}^{n - 1}\end{matrix} \qquad Equation 7$$

According to the equation 7, an n^{th} operation time (Δt₍ₙ₎) also changes exponentially to the number of charging (n). As the number of charging (n) increases, a time required for charging the pad capacitor to V_{HH} decreases exponentially.

Also, a total time consumed until the nth charging (T₍ₙ₎) may be represented as a sum of operation times (Δt₍ₙ₎). Since the operation time (Δt₍ₙ₎) has a geometric progression form, the total time (T₍ₙ₎) may be derived to a sum of geometric progressions. If k is set to Cₑₓₜ/C_{pad} (k=Cₑₓₜ/C_{pad}), as shown in a below equation 8, the total time (T₍ₙ₎) may be represented as an exponential function for n.

$${t}_{i} = \frac{{C}_{pad} {V}_{HH}}{I} {( \frac{k}{1 + k} )}^{i - 1} \\ {T}_{( n )} = {\sum }_{i = 1}^{n} {t}_{i} = \frac{{t}_{1} [ 1 - {( \frac{k}{1 + k} )}^{n} ]}{1 - \frac{k}{1 + k}} = \frac{\frac{{C}_{pad} {V}_{HH}}{I} [ 1 - {( \frac{k}{1 + k} )}^{n} ]}{\frac{1}{1 + k}} = \frac{{C}_{pad} {V}_{HH}}{I} ( 1 + k ) [ 1 - {( \frac{k}{1 + k} )}^{n} ] \\ \begin{matrix}{T}_{( n )} = \frac{{C}_{pad} {V}_{HH}}{I} \frac{{C}_{pad} + {C}_{ext}}{{C}_{pad}} [ 1 - {( \frac{{C}_{ext}}{{C}_{pad} + {C}_{ext}} )}^{n} ] \\ = \frac{{V}_{HH} ( {C}_{pad} + {C}_{ext} )}{I} [ 1 - {( \frac{{C}_{ext}}{{C}_{pad} + {C}_{ext}} )}^{n} ]\end{matrix} \qquad Equation 8$$

When the operation is repeated n times, a ratio of the total time (T₍ₙ₎) required for the voltage change (ΔV) means a mean gradient for charging the external capacitor (Cₑₓₜ).

$${V}_{ext ( n )} = {V}_{HH} [ 1 - {( \frac{{C}_{ext}}{{C}_{pad} + {C}_{ext}} )}^{n} ] \\ {T}_{( n )} = \frac{{V}_{HH} ( {C}_{pad} + {C}_{ext} )}{I} [ 1 - {( \frac{{C}_{ext}}{{C}_{pad} + {C}_{ext}} )}^{n} ] \qquad Equation 9$$

Therefore, the mean gradient may be represented as a below equation 10.

$${S}_{avg} = \frac{{V}_{ext ( n )}}{{T}_{( n )}} = \frac{{V}_{HH} [ 1 - {( \frac{{C}_{ext}}{{C}_{pad} + {C}_{ext}} )}^{n} ]}{\frac{{V}_{HH} ( {C}_{pad} + {C}_{ext} )}{I} [ 1 - {( \frac{{C}_{ext}}{{C}_{pad} + {C}_{ext}} )}^{n} ]} = \frac{I}{{C}_{pad} + {C}_{ext}} \qquad Equation 10$$

In other words, the gradient of the voltage change to a time required for charging the external capacitor (Cₑₓₜ) is linear and can be controlled by an electrostatic capacity (Cₑₓₜ) of the external capacitor, an electrostatic capacity of the electrode, and a static current (I) flowing there. When a human body contacts the electrode, the C_{pad} increases and the gradient decreases. On the contrary, when a human body does not contact the electrode, the gradient increases.

Similarly, a gradient during a single time operation period for charging the external capacitor (Cₑₓₜ) may be calculated by dividing the amount of voltage change (ΔVₑₓₜ₍ₙ₎) by the time of duration (Δt₍ₙ₎) as represented in the following equation 11.

$$\begin{matrix} Equation 11 \\ \begin{matrix}Δ {V}_{ext ( n )} = {V}_{ext ( n )} - {V}_{ext ( n - 1 )} \\ = {V}_{HH} [ 1 - {( \frac{{C}_{ext}}{{C}_{pad} + {C}_{ext}} )}^{n} ] - {V}_{HH} [ 1 - {( \frac{{C}_{ext}}{{C}_{pad} + {C}_{ext}} )}^{n - 1} ] \\ = {{V}_{HH} ( \frac{{C}_{ext}}{{C}_{pad} + {C}_{ext}} )}^{n - 1} [ 1 - \frac{{C}_{ext}}{{C}_{pad} + {C}_{ext}} ]\end{matrix} & \\ Δ {t}_{( n )} = \frac{{C}_{pad} {V}_{HH}}{I} {( \frac{{C}_{ext}}{{C}_{pad} + {C}_{ext}} )}^{n - 1} & \end{matrix}$$

Therefore, the period gradient (S₍ₙ₎) may be represented as the following equation 12.

$${S}_{( n )} = \frac{Δ {V}_{ext ( n )}}{Δ {t}_{( n )}} = \frac{{{V}_{HH} ( \frac{{C}_{ext}}{{C}_{pad} + {C}_{ext}} )}^{n - 1} [ 1 - \frac{{C}_{ext}}{{C}_{pad + {C}_{ext}}} ]}{\frac{{C}_{pad} {V}_{HH}}{I} {( \frac{{C}_{ext}}{{C}_{pad} + {C}_{ext}} )}^{n - 1}} = \frac{I}{{C}_{pad}} [ 1 - \frac{{C}_{ext}}{{C}_{pad} + {C}_{ext}} ] = \frac{I}{{C}_{pad} + {C}_{ext}} = {S}_{avg} \qquad Equation 12$$

The period gradient is identical to the above-described mean gradient. That is, a gradient for charging the external capacitor for each operation coincides with that of overall operation. In case of an ideal design, it is represented as a linear function regardless of the number of operations (n), and it is always a constant for design parameters.

Also, the following results can be derived from the above equations.

$${S}_{avg} = \frac{Δ {V}_{ext}}{Δ T} = \frac{I}{{C}_{pad} + {C}_{ext}} \\ Δ {V}_{ext} = \frac{I Δ T}{{C}_{pad} + {C}_{ext}} \\ Δ T = \frac{( {C}_{pad} + {C}_{ext} ) Δ {V}_{ext}}{I} \qquad Equation 13$$

The above equation has a form similar to the equations

$$Δ V = \frac{I Δ t}{C} and$$

$$Δ t = \frac{C Δ V}{I} ,$$

which are the equations for charging a single capacitor. Thus, even though the method proposed in the present invention is used, linear relations may be utilized.

Therefore, as described above, if the voltage (Vₑₓₜ) of the external capacitor is measured after performing the method for measuring electrostatic capacity using a current source according to an example embodiment of the present invention, the time required for reaching a reference voltage can be measured using a timer, and the amount of voltage change during a specific period can be measured using an ADC. Thus, it is possible to select one of various designs, and the gradient has linearity so that computation can be simplified. Also, since the charge sharing is used, a driving time of the external capacitor (Cₑₓₜ) can be made linearly longer so that high-speed clock is not needed for measuring, as compared with a case of charging and discharging by using only an electrode. Also, since the time for measuring may be extended even without using a small current and the number of repetitions for charging the external capacitor (Cₑₓₜ) is large, errors due to noise can be reduced.

### Example Embodiment 1

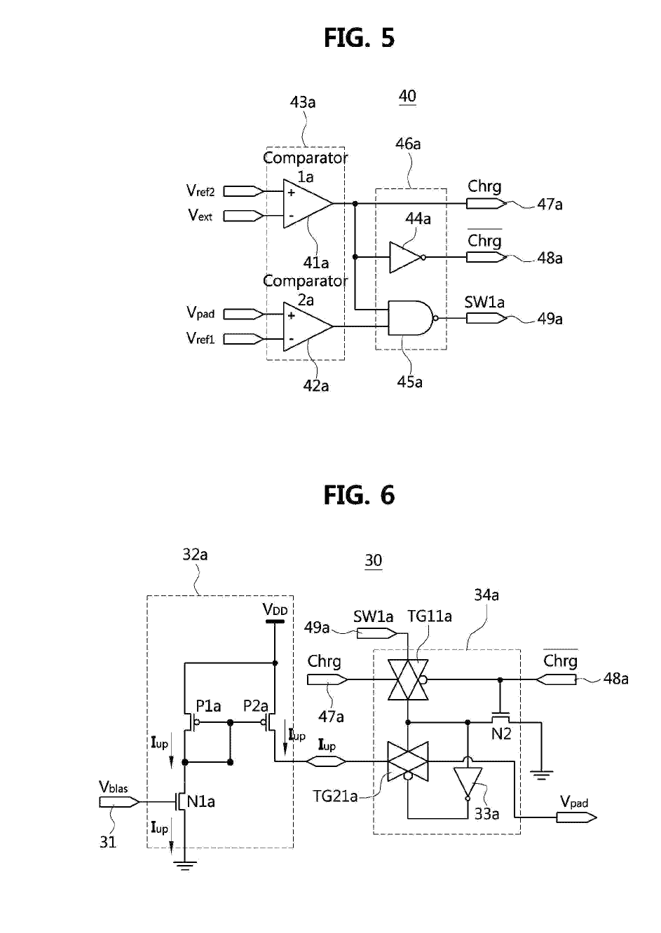

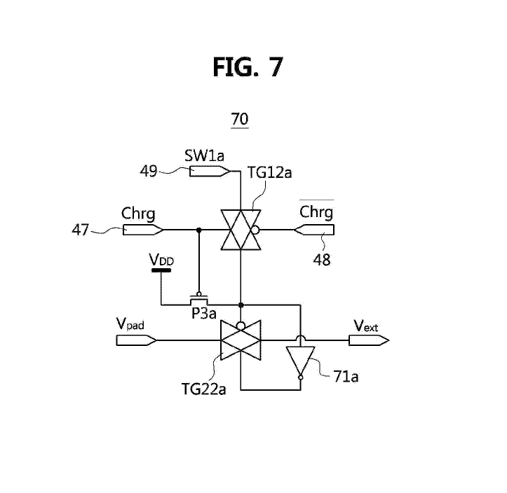

FIG. 4 is a circuit diagram illustrating a circuit for measuring electrostatic capacity using a current source based on current charging and charge sharing method according to the present invention. FIG. 5 illustrates a circuit for controlling charging operations of a charging part of FIG. 4. FIG. 6 is a circuit diagram illustrating an example of the charging part of FIG. 4. FIG. 7 is a circuit diagram illustrating an example of a charge sharing switching part of FIG. 4.

Referring to FIG. 4, the circuit for measuring electrostatic capacity using a current source according to an example embodiment of the present invention may comprise a plurality of pad capacitors (C_{pad1}, C_{pad2}, . . . , C_{padN}) each of which corresponds to each of multiple lines, a multiplexor (MUX) 10, a charging part 30a, a discharging part 50a, a charge sharing switching part 70a, and a reset switching part 90a. The charging part 30a includes a static current source 32 and a charging switching part 34 (SW1a). The discharging part 50a includes a discharging switching part (SW2a).

The multiplexor 10 selects a touch pad electrode to be measured among a plurality of touch pad electrodes.

The charging part 30a charges a selected pad capacitor (C_{pad}) using the static current source 32.

The discharging part 50a discharges the selected pad capacitor (C_{pad}) through a switching operation.

The charge sharing switching part 70a is located between the pad capacitor (C_{pad}) and an external capacitor (Cₑₓₜ), and performs operations for charge sharing between the pad capacitor (C_{pad}) and the external capacitor (Cₑₓₜ).

The reset switching part 90a grounds the external capacitor so as to discharge the external capacitor.

After a touch pad electrode is selected by the multiplexor 10, a pad capacitor corresponding to the selected touch pad electrode is initialized by the discharging part 50a, and a touch pad electrode voltage V_{pad} and an external voltage Vₑₓₜ are compared with reference voltages V_{ref1} and V_{ref2} in a comparator 43a of FIG. 5. Outputs of the comparator 43a are used for controlling switches SW1a, SW2a, and SW3a of the electrostatic capacity measuring circuit through logical operations.

In a charging period, charging and charge sharing on the pad capacitor (C_{pad}) are repeated by operating SW1 and SW3 in turn. Also, in a discharging period, discharging and charge sharing on the pad capacitor (C_{pad}) are repeated by operating SW2 and SW3 in turn.

Hereinafter, an operation of the circuit for measuring electrostatic capacity using a current source according to an example embodiment of the present invention will be explained in detail.

Before charging the pad capacitor (C_{pad}) of FIG. 4 to a first reference voltage (V_{ref1}) and the external capacitor (Cₑₓₜ) of FIG. 4 to a second reference voltage (V_{ref2}), the two capacitors are initially in discharged state. That is, the pad capacitor (C_{pad}) is grounded to a ground voltage (GND) by the discharging part 50a (SW2a), and the external capacitor (Cₑₓₜ) is grounded to the ground voltage (GND) by the reset switching part (SW4a), and then all of the pad capacitor and the external capacitor are made to be in discharged state.

The pad capacitor (C_{pad}) is charged by the static current source 32 and the charging switching part SW1a. After the charging is completed, the charge sharing switching part 70a (SW3 or /SW1a), which operates oppositely to the charging switching part 34 (SW1a), makes the charges of the pad capacitor (C_{pad}) and the external capacitor (Cₑₓₜ) be shared. The external capacitor (Cₑₓₜ) is charged by repeating charging on the pad capacitor and the charge sharing between the pad capacitor and the external capacitor.

Referring to FIG. 5, two comparators 41a and 43a are used for respectively comparing the voltage of the pad capacitor (V_{pad}) and the voltage of the external capacitor (Vₑₓₜ). The first reference voltage (V_{ref1}) is higher than the second reference voltage (V_{ref2}).

In order for the circuit for measuring electrostatic circuit to perform charging, the voltage of the external capacitor (Vₑₓₜ) should be lower than the second reference voltage (V_{ref1}). In order to control charging operation on the external capacitor (Cₑₓₜ), the first comparator 41a compares Vₑₓₜ with V_{ref2}, and outputs ‘High’ always when V_{ref1} is higher than Vext. This state may be defined as a charging signal (‘Chrg’). Also, the inverse state ‘Low’ of the charging signal may be defined as ‘/Chrg’. The second comparator 42a compares V_{pad} with V_{ref1}, and outputs ‘High’ when V_{pad} is higher than V_{ref1}. NAND operation on the charging signal (Chrg) and the output signal of the second comparator 42a may determine a charging control signal 49a (SW1) according to statuses of V_{pad} and Vₑₓₜ as shown in a below table 1.

TABLE 1

| Status | | Comparator 1 | Comparator 2 | Chrg | /Chrg | SW1 |
|---|---|---|---|---|---|---|
| Vₑₓₜ < | V_{pad} < | High | Low | High | Low | High |
| V_{ref2} | V_{ref1} | | | | | |
| Vₑₓₜ < | V_{pad} > | High | High | High | Low | Low |
| V_{ref2} | V_{ref1} | | | | | |
| Vₑₓₜ > | V_{pad} < | Low | Low | Low | High | High |
| V_{ref2} | V_{ref1} | | | | | |
| Vₑₓₜ > | V_{pad} > | Low | High | Low | High | High |
| V_{ref2} | V_{ref1} | | | | | |

Referring to FIG. 6, the charging part 30 may include a static current source 32a and a charging switching part 34a. In order to make a static current flow, a voltage V_{bias} is applied to a gate terminal of a NMOS transistor N1a, and so a static current Iᵤₚ flows from a drain terminal to a source terminal of the NMOS transistor N1a. A current identical to the current Iᵤₚ flows to a terminal Iᵤₚ by a current mirror configured with PMOS transistors P1a and P2a. The charging switch for charging the pad capacitor (C_{pad}) comprises a transmission gate TG21a, and operation of the charging switch may be controlled by a charging control switch comprising another transmission gate TG11a. If the charging signal (Chrg) is ‘High’, the transmission gate TG11a acting as the charging control switch is turned on, and a charging control signal SW1 is provided to the transmission gate TG21a acting as the charging switch, and makes the charging switch be turned on or off. If the charging signal (Chrg) is ‘High’, the charging control switch is turned off. Then, since the signal ‘/Chrg’ becomes ‘High’, a NMOS transistor N2 is turned on, and thus the charging switch is turned off by a ground voltage (GND).

Referring to FIG. 7, configuration and operation scheme of a sharing switch in the charge sharing switching part 70 are similar to those of the charging switch. For example, the sharing switch may be implemented using a transmission gate TG22a. In a region that the charging signal ‘Chrg’ is ‘High’, the sharing switch operates oppositely to the charging switch. That is, in the region that the charging signal ‘Chrg’ is ‘High’, if the charging switch is turned on, the sharing switch is turned off. Also, if the charging switch is turned off, the sharing switch is turned off. In a region that the charging signal ‘Chrg’ is ‘Low’, the sharing switch is turned of and the charging operation on the external capacitor (Cₑₓₜ) is stopped. The following table 2 represents operation statuses of Chrg, /Chrg, SW1, the charging switch, and the sharing to switch.

TABLE 2

| | Chrg | /Chrg | SW1 | Charging switch | Sharing switch |
|---|---|---|---|---|---|
| Status | High | Low | High | ON | OFF |
| | High | Low | Low | OFF | ON |
| | Low | High | High | OFF | OFF |

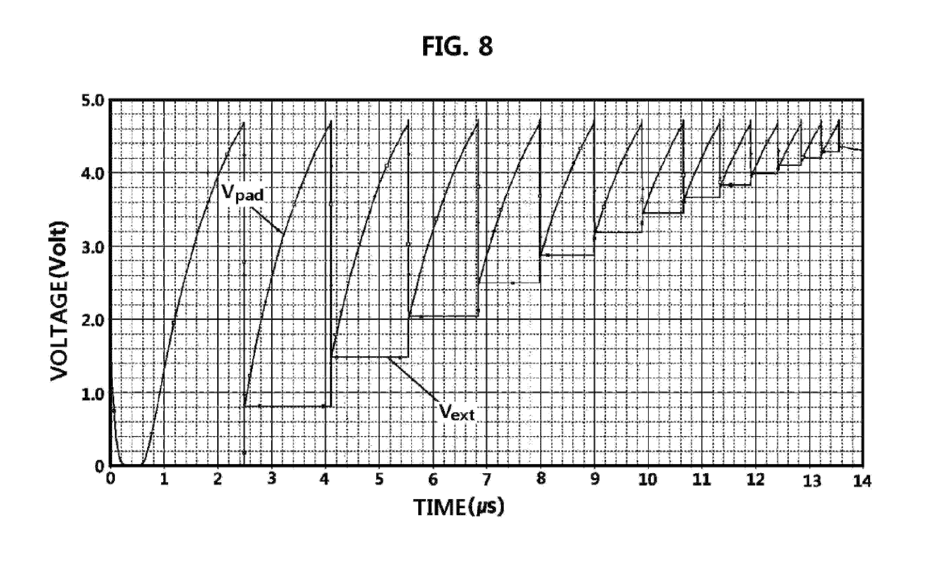

FIG. 8 illustrates results of simulation on the circuit for measuring electrostatic capacity using a current source of FIG. 4. After an initial reset, as time elapses, the pad capacitor (C_{pad}) is charged, so that the voltage of the pad capacitor (V_{pad}) reaches the reference voltage V_{ref1} and then the voltages of the external capacitor (Cₑₓₜ) and the pad capacitor (C_{pad}) become identical due to charge sharing. By repeating the above operations, the voltage of the external capacitor (Cₑₓₜ) increases stepwise, and an increase gradient of the voltage is near linear as shown in the above-described equation. Supposing no leakage currents in the circuit, actual operation becomes more similar to computed results.

### Example Embodiment 2

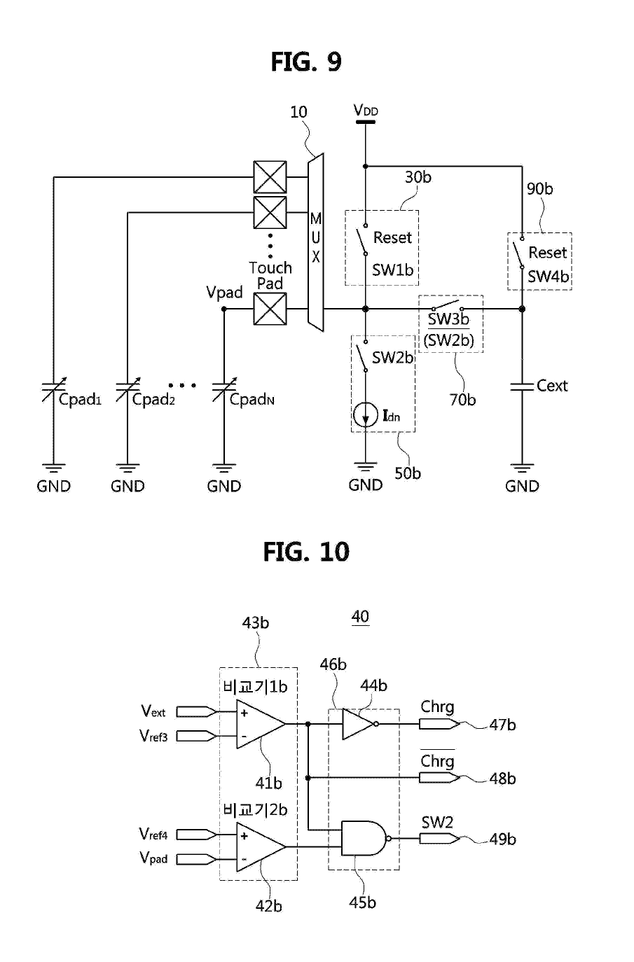

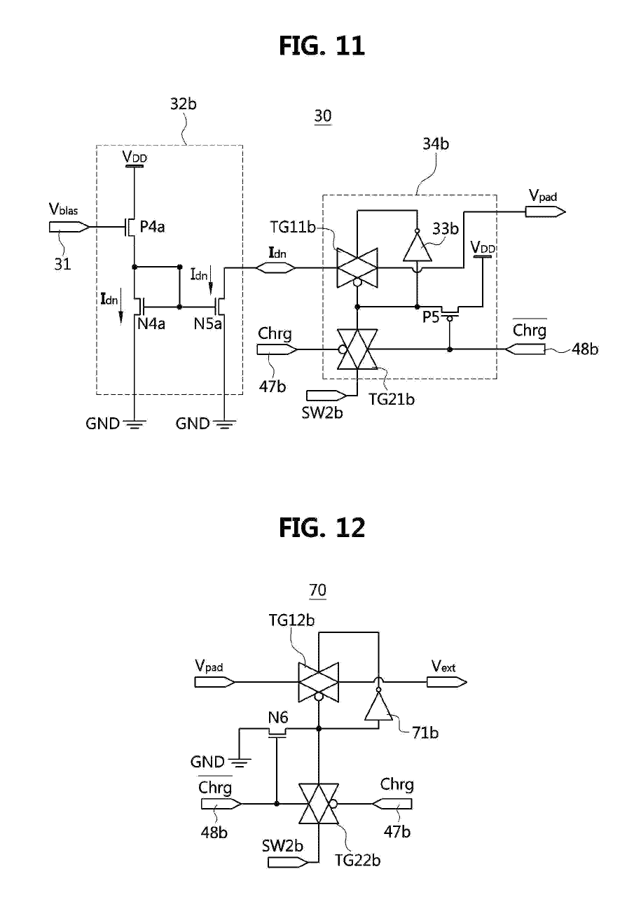

FIG. 9 is a circuit diagram illustrating a circuit for measuring electrostatic capacity using a current source based on current charging and charge sharing method according to another example embodiment of the present invention. FIG. 10 illustrates a circuit for controlling discharging operations of a discharging part of FIG. 4. FIG. 11 is a circuit diagram illustrating an example of the discharging part of FIG. 9. FIG. 12 is a circuit diagram illustrating an example of a charge sharing switching part of FIG. 9.

Referring to FIG. 9, the circuit for measuring electrostatic capacity using a current source according to another example embodiment of the present invention may comprise a plurality of pad capacitors (C_{pad1}, C_{pad2}, . . . , C_{padN}) each of which corresponds to each of multiple lines, a multiplexor (MUX) 10, a discharging part 50b, a charge sharing switching part 70b, and reset switching parts 30b and 90a. The discharging part 50b includes a discharging switching part SW2b.

The multiplexor 10 selects a touch pad electrode to be measured among a plurality of touch pad electrodes.

The discharging part 50b discharges the selected pad capacitor (C_{pad}) through a switching operation.

The charge sharing switching part 70b is located between the pad capacitor (C_{pad}) and the external capacitor (Cₑₓₜ), and performs operations for charge sharing between the pad capacitor (C_{pad}) and the external capacitor (Cₑₓₜ).

The reset switching part 30b raises the voltage of the pad capacitor (V_{pad}) to V_{DD} so as to reset the voltage of the pad capacitor.

The reset switching part 90b raises the voltage of the external capacitor (Vₑₓₜ) to V_{DD} so as to reset the voltage of the external capacitor (Vₑₓₜ).

After a touch pad electrode is selected by the multiplexor 10, a pad capacitor corresponding to the selected touch pad electrode is initialized by the reset switching part 30b, and the touch pad electrode voltage V_{pad} and the external voltage Vₑₓₜ are compared with reference voltages V_{ref3} and V_{ref4} in a comparator 43b of FIG. 10. Outputs of the comparator 43b are used for controlling switches SW1b, SW2b, and SW3b of the electrostatic capacity measuring circuit through logical operations.

In a discharging period, discharging and charge sharing of the pad capacitor (C_{pad}) are repeated by operating SW2b and SW3b in turn.

Hereinafter, an operation of the circuit for measuring electrostatic capacity using a current source according to another example embodiment of the present invention will be explained in detail.

Referring to FIG. 4, in order to discharge the pad capacitor (C_{pad}) to the fourth reference voltage (V_{ref4}) and the external capacitor to the third reference voltage (V_{ref3}), the two capacitors should be initially in charged state. Initially, the pad capacitor and the external capacitor are raised to a source voltage (V_{DD}) by two reset switching parts 30b and 90b. According to operations of the static current source and discharging switch SW2b, the pad capacitor (C_{pad}) is discharged. After the discharging is completed, the charge sharing switches 70b, SW3b or /SW2b, which operate oppositely to the discharging switch SW2b, perform charge sharing between the pad capacitor and the external capacitor. The external capacitor (Cₑₓₜ) is discharged by repeating discharging of the pad capacitor and charge sharing.

Referring to FIG. 10, two comparators are used for respectively comparing the voltage of the pad capacitor (V_{pad}) and the voltage of the external capacitor (Vₑₓₜ). The third reference voltage (V_{ref3}) is higher than the fourth reference voltage (V_{ref4}). In order for the circuit for measuring electrostatic circuit to perform discharging, the voltage of the external capacitor (Vₑₓₜ) should be higher than the third reference voltage (V_{ref3}). In order to control discharging operation on the external capacitor (Cₑₓₜ), the comparator 41b compares Vₑₓₜ with V_{ref3}, and outputs ‘High’ when Vₑₓₜ is higher than V_{ref3}. This state may be defined as a discharging signal (‘/Chrg’). Also, the inverse state ‘Low’ of the discharging signal may be defined as ‘Chrg’. The comparator 42b compares V_{pad} with V_{ref4}, and outputs ‘High’ when V_{pad} is lower than V_{ref4}. NAND operation on the discharging signal (‘/Chrg’) and the output signal of the comparator 42b may determine a discharging control signal (SW2) according to statuses of V_{pad} and Vₑₓₜ as shown in a below table 3.

TABLE 3

| Status | | Comparator 1 | Comparator 2 | Chrg | /Chrg | SW2 |
|---|---|---|---|---|---|---|
| Vₑₓₜ > | V_{pad} > | High | Low | Low | High | High |
| V_{ref3} | V_{ref4} | | | | | |
| Vₑₓₜ > | V_{pad} < | High | High | Low | High | Low |
| V_{ref3} | V_{ref4} | | | | | |
| Vₑₓₜ < | V_{pad} > | Low | Low | High | Low | High |
| V_{ref3} | V_{ref4} | | | | | |
| Vₑₓₜ < | V_{pad} < | Low | High | High | Low | High |
| V_{ref3} | V_{ref4} | | | | | |

Referring to FIG. 11, the discharging part 50b may include a static current source 32b and a discharging switching part SW2b. In order to make a static current flow, a voltage V_{bias} is applied to a gate terminal of a PMOS transistor P4a, and so a static current I_{dn} flows from a source terminal to a drain terminal of the PMOS transistor P4a. A current identical to the current I_{dn} flows to an I_{dn} terminal by a current mirror configured with NMOS transistors N4a and N5a. The discharging switch for discharging the pad capacitor (C_{pad}) comprises a transmission gate TG11b, and operation of the discharging switch may be controlled by a discharging control switch comprising another transmission gate TG21b. If the charging signal (Chrg) is ‘Low’, the discharging control switch is turned on, and a discharging control signal SW2 is provided to the transmission gate TG11b acting as the discharging switch, and makes the discharging switch be turned on or off. If the charging signal (Chrg) is ‘High’, the discharging control switch comprising the transmission gate TG21b is turned off. Then, since the signal ‘/Chrg’ becomes ‘Low’, a PMOS transistor P5 is turned on, and thus the discharging switch is turned off by the source voltage (V_{DD}).

Referring to FIG. 12, configuration and operation scheme of a sharing switch in the charge sharing switching part 70b are similar to those of the discharging switch. In a region that the charging signal ‘Chrg’ is ‘Low’, the sharing switch operates oppositely to the discharging switch. That is, in the region that the charging signal ‘Chrg’ is ‘Low’, if the discharging switch is turned on, the sharing switch is turned off. Also, if the discharging switch is turned of the sharing switch is turned on. In a region that the charging signal ‘Chrg’ is ‘High’, the sharing switch is turned off, and the discharging operation on the external capacitor (Cₑₓₜ) is stopped. The following table 4 represents operation statuses of Chrg, /Chrg, SW2, the discharging switch, and the sharing switch.

TABLE 4

| | Chrg | /Chrg | SW2 | Discharging switch | Sharing switch |
|---|---|---|---|---|---|
| Status | Low | High | High | OFF | ON |
| | Low | High | Low | ON | OFF |
| | High | Low | High | OFF | OFF |

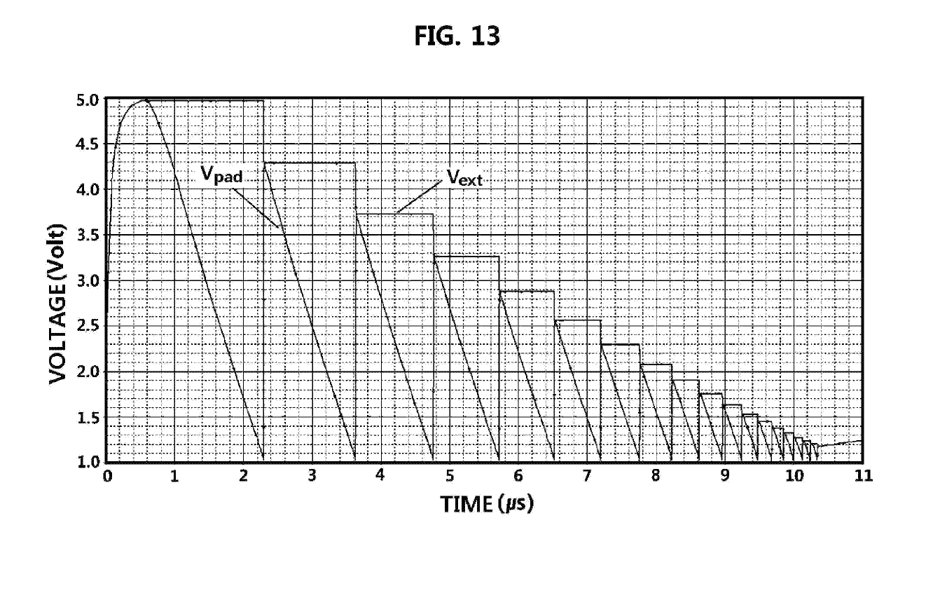

FIG. 13 illustrates results of simulation on the circuit for measuring electrostatic capacity using a current source of FIG. 9. After an initial reset, as time elapses, the pad capacitor (C_{pad}) is discharged, so that the voltage of the pad capacitor (V_{pad}) reaches the reference voltage V_{ref4} and then the voltages of the external capacitor (Cₑₓₜ) and the pad capacitor (C_{pad}) become identical due to charge sharing. By repeating the above operations, the voltage of the external capacitor (Cₑₓₜ) decreases stepwise, and a decrease gradient of the voltage is near linear similarly to the example embodiment 1. Supposing no leakage currents in the circuit, actual operation becomes more similar to computed results.

### Example Embodiment 3

### A Circuit for Measuring Electrostatic Capacity Using Charging/Discharging and Charge Sharing Method (FIGS. 7-9)

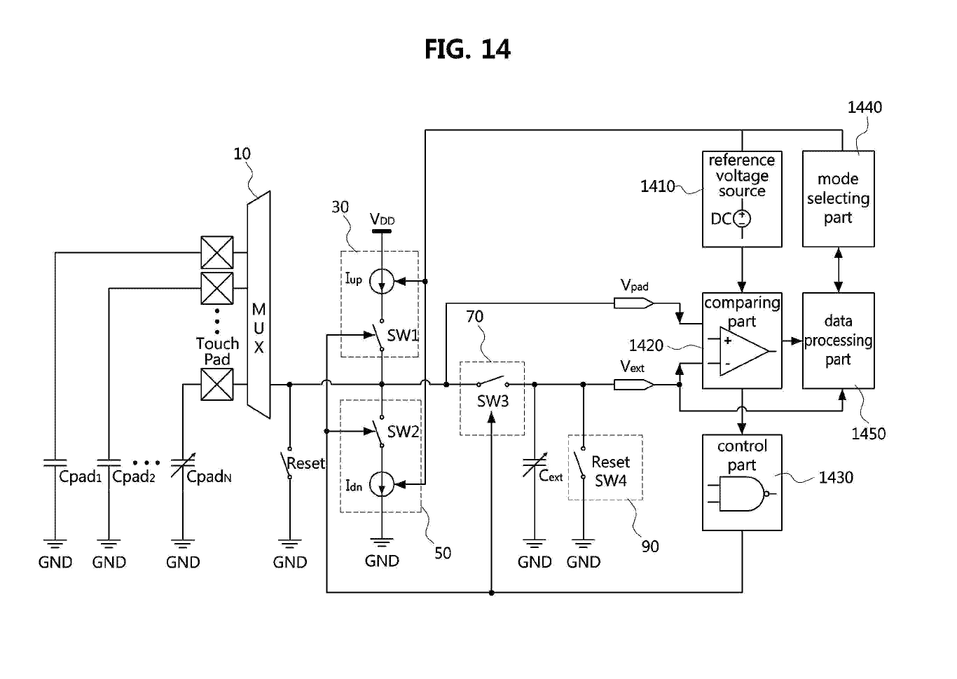

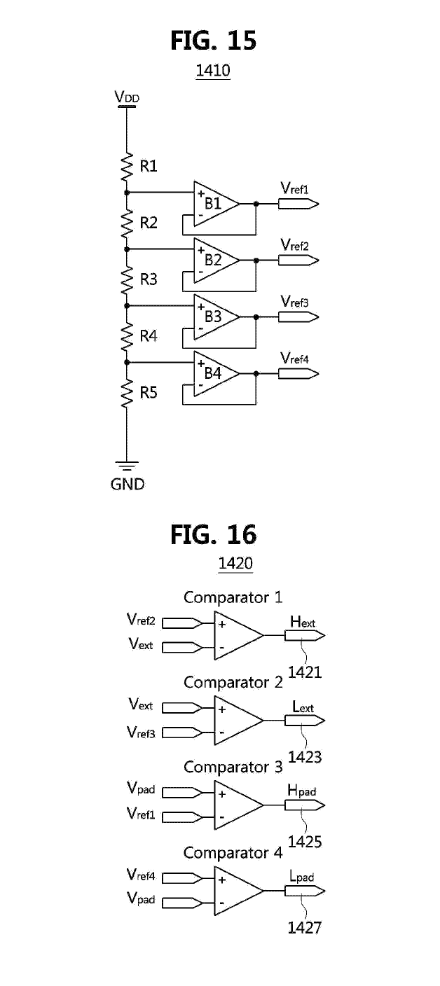

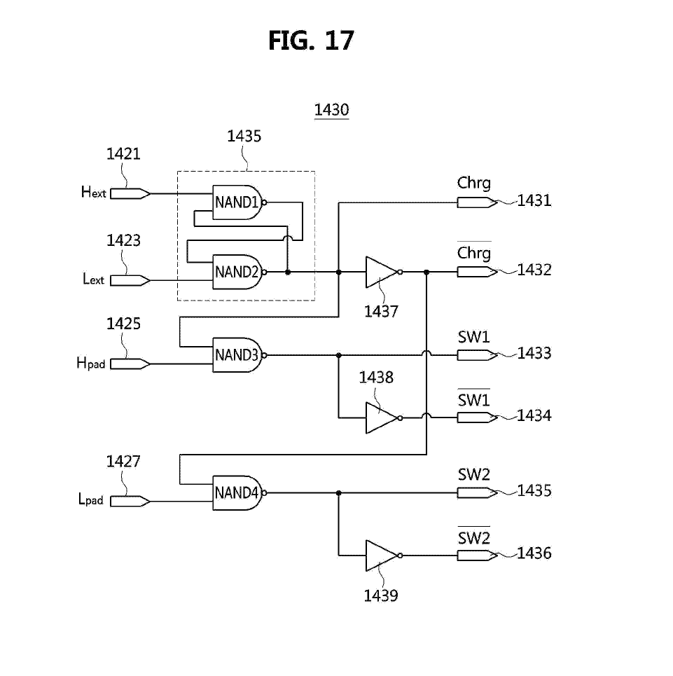

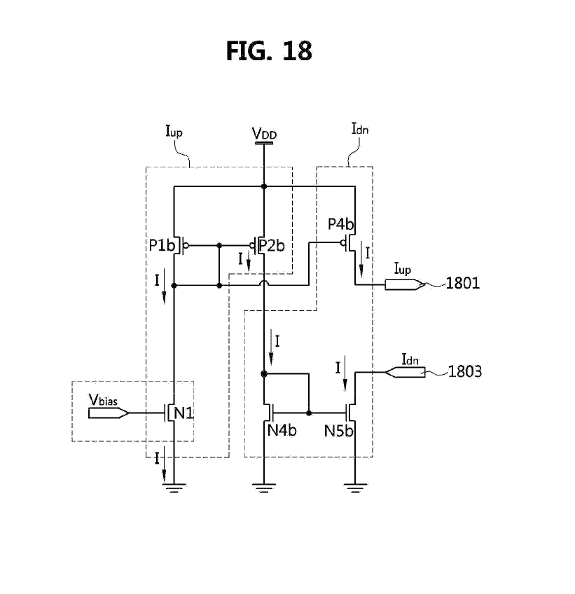

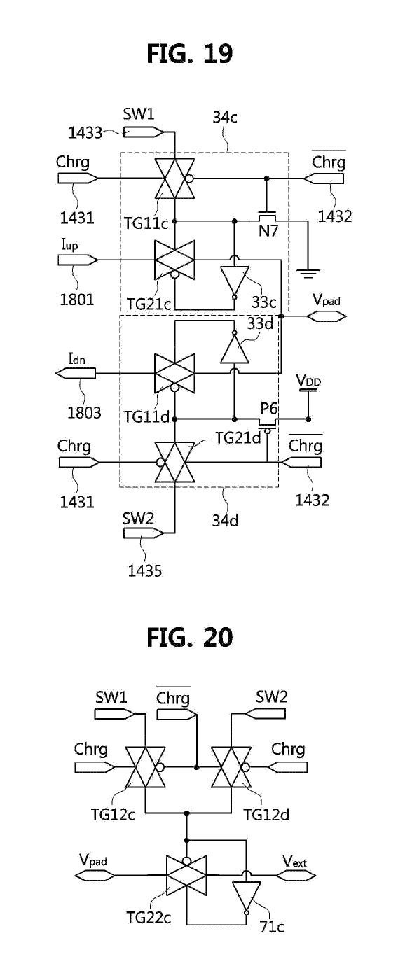

FIG. 14 is a circuit diagram illustrating a circuit for measuring electrostatic capacity using a current source based on current charging/discharging and charge sharing method according to other example embodiment of the present invention. FIG. 15 illustrates an example of a reference voltage generating circuit for generating reference voltages used for a circuit for measuring electrostatic capacity using a current source. FIG. 16 illustrates an example of a circuit for comparator used for a circuit for measuring electrostatic capacity using a current source. FIG. 17 illustrates a charging/discharging control circuit for controlling charging and discharging operations of a charging part and a discharging part of FIG. 14. FIG. 18 is a circuit diagram illustrating an example of a charging/discharging static current source circuit of the charging/discharging part (the charging part and the discharging part). FIG. 19 is a circuit diagram illustrating an example of a charging/discharging switch for charging/discharging part (the charging part and the discharging part). FIG. 20 is a circuit diagram illustrating an example of a charge sharing switching part of FIG. 14.

The circuit for measuring electrostatic capacity according to the example embodiment 3 of FIG. 14 is a circuit using both the charging method of the example embodiment 1 and the discharging method of the example embodiment 2. A one-way circuit, which operates according to the charging method or the discharging method, has a disadvantage of large power consumption when charging or discharging is performed by an initial reset operation. According to the example embodiment 3 of the present invention, a two-way circuit, which is designed to switch charging and discharging automatically using logic circuits, may be configured. In this case, an amount of voltage change caused by grounding to the ground voltage (GND) or charging to the source voltage (V_{DD}), during the initial reset operations, can be decreased, so that power consumption may be reduced. Also, a time for a single charging and discharging cycle of the external capacitor may be increased near twice, so that a margin for measurement on difference of electrostatic capacity of the pad capacitor (C_{pad}).

Referring to FIG. 14, the circuit for measuring electrostatic capacity using a current source according to other example embodiment of the present invention may comprise a plurality of pad capacitors (C_{pad1}, C_{pad2}, . . . , C_{padN}) each of which corresponds to each of multiple lines, a multiplexor (MUX) 10, a charging/discharging part, a charge sharing switching part 70, and a reset switching parts 90 (SW4). The discharging part 50b includes a discharging switching part SW2b. The charging/discharging part may comprise a charging part 30 and a discharging part 50. The circuit for measuring electrostatic capacity using a current source according to other example embodiment of the present invention may further comprise a reference voltage generating circuit 1410, a comparing part 1420, and a charging/discharging control circuit 1430. The circuit for measuring electrostatic capacity using a current source according to other example embodiment of the present invention may further comprise a mode selecting part 1440 and a data processing part 1450.

The multiplexor 10 selects a touch pad electrode to be measured among a plurality of touch pad electrodes.

The charging part 30 charges the selected pad capacitor (C_{pad}) using a static current source Iup.

The discharging part 50 discharges the selected pad capacitor (C_{pad}) using a static current source Idn through a switching operation.

The charge sharing switching part 70 is located between the pad capacitor (C_{pad}) and the external capacitor (Cₑₓₜ), and performs operations for charge sharing between the pad capacitor (C_{pad}) and the external capacitor (Cₑₓₜ).

The reset switching parts 30c and 90 comprise a reset switch 30c located between the pad capacitor having the voltage (V_{pad}) and the ground voltage (GND) and a reset switch 90 located between the voltage of external capacitor (Vₑₓₜ) and the ground voltage.

The reset switch 30c resets the voltage of the pad capacitor by grounding the voltage of the pad capacitor (V_{pad}).

The reset switch 90 resets the voltage of the external capacitor by grounding the voltage of the external capacitor (Vₑₓₜ).

The external voltage (Vₑₓₜ) and outputs of the comparing part 1420 are inputted to the data processing part 1450 to be used for calculating electrostatic capacity. Also, the mode selecting part 1440 operates according to results of the data processing and then modifies an amount of current (I) and the value of the external capacitor (Cₑₓₜ) so as to adjust an operation time, margin of measurement, consumed power, etc.

Hereinafter, an operation of the circuit for measuring electrostatic capacity using a current source according to other example embodiment of the present invention will be explained in detail.

Referring to FIG. 14, the circuit for measuring electrostatic capacity using a current source according to other example embodiment of the present invention determines direction of operation (charging or discharging) according to the voltage of the pad capacitor (V_{pad}) and the voltage of the external capacitor (Vₑₓₜ), and the controls various switches in the circuit through feedbacks.

The comparing part 1420 compares the voltages V_{pad} and Vₑₓₜ with the reference voltages V_{ref1}, V_{ref2}, V_{ref3}, and V_{ref4}, and generates logic control signals Hₑₓₜ, Lₑₓₜ, H_{pad}, and L_{pad}, and then outputs the generated logic control signals to the charging/discharging control circuit 1430 and the data processing part 1450.

As shown in FIG. 17, the charging/discharging control circuit 1430 may be configured with a logic circuit for controlling switches in the circuit based on the logic control signals Hₑₓₜ, Lₑₓₜ, H_{pad}, and L_{pad}, which are generated in the comparing part 1420. Output signals from the charging/discharging control circuit 1430 are provided to the charging/discharging switches SW1 and SW2 and the charge sharing switch 70 and make the circuit repeat charging and charge sharing or discharging and charge sharing by operating the corresponding switches.

Also, in the example embodiment 3, the data processing part 1450 may measure a charging/discharging time using a timer. The signal of the comparing part 1420 changes for one or more charging/discharging cycles. If the signal is provided to the data processing part 1420 and thus a cycle time is measured, a change on C_{pad} according to whether a human body touches or not can be measured.

Referring to FIG. 15, the reference voltage generating circuit may generate the reference voltages by voltage-division based on serially connected resistors and by using buffers. In FIG. 15, an implementation example in which five resistors R1 to R5 and four buffers B1, B2, B3, and B4 are used is illustrated. Here, V_{ref1}>V_{ref2}>V_{ref3}>V_{ref4}.

Referring to FIG. 16, since both charging operation and discharging operation are demanded, the comparing part 1420 uses four comparators.

First, in order for the overall circuit to perform charging, the voltage of Cₑₓₜ should be lower than V_{ref2}. In order to control charging operation on Cₑₓₜ, the first comparator compares Vₑₓₜ with V_{ref2} and outputs ‘High’ always when Vₑₓₜ<V_{ref2}. The output terminal of the first comparator may be defined as ‘Hₑₓₜ’.

In order for the overall circuit to perform discharging, the voltage of Cₑₓₜ should be higher than V_{ref3}. In order to control the discharging operation on Cₑₓₜ, the second comparator compares Vₑₓₜ with V_{ref3}, and outputs ‘High’ always when Vₑₓₜ>V_{ref3}. The output terminal of the second comparator is defined as ‘Lₑₓₜ’. The third comparator compares V_{pad} with V_{ref1}, and outputs ‘High’ always when V_{pad}>V_{ref1}. The output terminal of the third comparator is defined as ‘H_{pad}’. The fourth comparator compares V_{pad} with V_{ref4}, and outputs ‘High’ always when V_{pad}<V_{ref4}. The output terminal of the fourth comparator is defined as ‘L_{pad}’. A below table 5 represents the voltage of pad capacitor and statuses of Hₑₓₜ, Lₑₓₜ, H_{pad}, and L_{pad} which are outputs of the first to fourth comparators according to the voltage of external capacitor.

TABLE 5

| | | Comparator 1 | Comparator 2 | Comparator 3 | Comparator 4 |
|---|---|---|---|---|---|
| Status | | (Hext) | (Lext) | (Hpad) | (Lpad) |
| Vₑₓₜ < V_{ref3} | V_{pad} < V_{ref4} | High | Low | Low | High |
| Vₑₓₜ < V_{ref3} | V_{ref4} < V_{pad} < V_{ref1} | High | Low | Low | Low |
| Vₑₓₜ < V_{ref3} | V_{ref1} < V_{pad} | High | Low | High | Low |
| V_{ref3} < Vₑₓₜ < V_{ref2} | V_{pad} < V_{ref4} | High | High | Low | High |
| V_{ref3} < Vₑₓₜ < V_{ref2} | V_{ref4} < V_{pad} < V_{ref1} | High | High | Low | Low |
| V_{ref3} < _{Vext} < V_{ref2} | V_{ref1} < V_{pad} | High | High | High | Low |
| V_{ref2} < Vₑₓₜ | V_{pad} < V_{ref4} | Low | High | Low | High |
| V_{ref2} < Vₑₓₜ | V_{ref4} < V_{pad} < V_{ref1} | Low | High | Low | Low |
| V_{ref2} < Vₑₓₜ | V_{ref1} < V_{pad} | Low | High | High | Low |

Referring to FIG. 17, the charging/discharging control circuit 1430 may be implemented as a logic circuit comprising NAND elements which uses the outputs Hₑₓₜ, Lₑₓₜ, H_{pad}, and L_{pad} of the comparing part 1420.

First, controls on charging operation and discharging operation may be made possible by using the signals Hₑₓₜ and Lₑₓₜ. When Hₑₓₜ is ‘High’, charging operation is performed. Also, when Lₑₓₜ is ‘High’, discharging operation is performed.

When V_{ref3}<Vₑₓₜ<V_{ref2}, both Hₑₓₜ and Lₑₓₜ output ‘High’. At this time, if a high impedance state is made, the circuit may continue charging operation when it is performing charging operation and discharging operation when it is performing discharging operation. Therefore, the charging signal ‘Chrg’ and the discharging signal ‘/Chrg’ can be made as NAND-type latches to which Hₑₓₜ and Lₑₓₜ are inputted. Since a case that both Hₑₓₜ and Lₑₓₜ are ‘Low’ does not exist, a state in which both output terminals of the latch are ‘High’ also does not exist. A part generating the charging signal (‘Chrg’) and the discharging signal (‘/Chrg’) does not have to be implemented as a NAND-type latch, so that it can be configured with various types of latch or flip-flop.

As described in the example embodiment 1, the charging control signal SW1 is generated using the signals ‘Chrg’ and ‘H_{pad}’ as inputs to the NAND element. Also, as described in the example embodiment 2, the discharging control signal SW2 is generated using the signals ‘/Chrg’ and ‘L_{pad}’ for inputs as inputs to the NAND element. The following table 6 is a table representing statuses of Chrg, /Chrg, SW1, and SW2 according to the outputs Hₑₓₜ, Lₑₓₜ, H_{pad}, and L_{pad} of the comparators.

TABLE 6

| Comparator 1 | Comparator 2 | Comparator 3 | Comparator 4 | | | | |
|---|---|---|---|---|---|---|---|
| (Hₑₓₜ) | (Lₑₓₜ) | (H_{pad}) | (L_{pad}) | Chrg | /Chrg | SW1 | SW2 |
| High | Low | Low | High | High | Low | High | High |
| High | Low | Low | Low | High | Low | High | High |
| High | Low | High | Low | High | Low | Low | High |
| High | High | Low | High | HZ | HZ | High | Low/ |
| | | | | | | | High |
| High | High | Low | Low | HZ | HZ | High | High |
| High | High | High | Low | HZ | HZ | Low/ | High |
| | | | | | | High | |
| Low | High | Low | High | Low | High | High | Low |
| Low | High | Low | Low | Low | High | High | High |
| Low | High | High | Low | Low | High | High | High |

Referring to FIG. 18, when a bias voltage (V_{bias}) is applied to a gate terminal of an NMOS transistor N1 of the charging/discharging static current source circuit, a current (I) flows from a drain terminal to a source terminal. A current identical to the current I is made to to flow to an Iᵤₚ terminal by a current mirror comprising PMOS transistors P1b and P2b, and the current mirror makes the identical current flow to a current mirror comprising other NMOS transistors N4b and N5b. The identical current is made to flow to an I_{dn} terminal by the current mirror comprising the NMOS transistors N4b and N5b. Configuration of a bias element and the current mirrors is not restricted to an example of the circuit of FIG. 18, and may be modified variously.

Referring to FIG. 19, the charging switch 34c operates based on configuration and theory identical to those of the charging switching part 34a of the example embodiment 1 of FIG. 6, and the discharging switch 34d operates based on configuration and theory identical to those of the charging switching part 34b of the example embodiment 2. During the charging operation, the signal SW1 is provided to the charging switch and the discharging switch is turned off. On the contrary, during the discharging operation, the signal SW2 is provided to the discharging switch and the charging switch is turned off.

Referring to FIG. 20, the charge sharing switching part 70 may comprise a charging control switch configured with a transmission gate TG12c, a discharging control switch configured with a transmission gate TG12d, and a sharing switch comprising a transmission gate TG22c. The sharing switch operates differently from operations of the example embodiments 1 and 2. The sharing switch operates exclusively for the charging operation and the discharging operation. During charging operation, the sharing switch operates oppositely to the charging switch. Also, during discharging operation, the sharing switch operates oppositely to the discharging switch. Thus, a path selector using the signals ‘Chrg’ and ‘/Chrg’ may be used. The following table 7 is a table representing statuses of the charging switch, the discharging switch and the sharing switch according to Chrg, /Chrg, SW1, and SW2.

TABLE 7

| | | | | Charging | Discharging | Sharing |
|---|---|---|---|---|---|---|
| Chrg | /Chrg | SW1 | SW2 | switch | switch | switch |
| High | Low | High | High | ON | OFF | OFF |
| High | Low | Low | High | OFF | OFF | ON |
| Low | High | High | High | OFF | OFF | ON |
| Low | High | High | Low | OFF | ON | OFF |

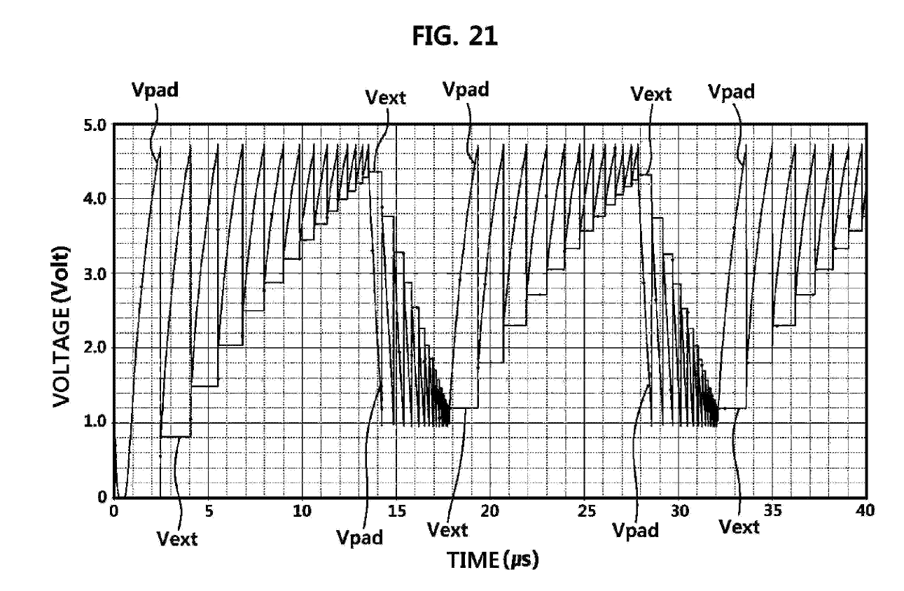

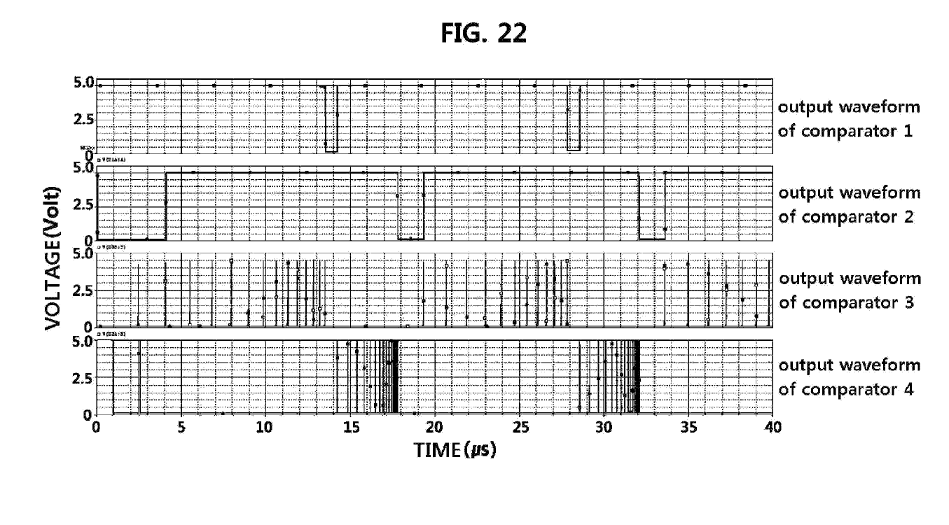

FIG. 21 illustrates results of simulation on the circuit for measuring electrostatic capacity of FIG. 14. After a reset, as time elapses, the pad capacitor (C_{pad}) is charged to the reference voltage V_{ref1} and then the voltages of the external capacitor (Cₑₓₜ) and the pad capacitor (C_{pad}) become identical due to charge sharing. By repeating the above operations, the voltage of the external capacitor (Cₑₓₜ) increases stepwise, and an increase gradient of the voltage is near linear similarly to the example embodiment 1. When the voltage of the external capacitor reaches V_{ref2}, operation of the circuit is switched from charging operation to discharging operation. As time elapses, the pad capacitor (C_{pad}) is discharged to the reference voltage V_{ref4} and then the voltages of the external capacitor (Cₑₓₜ) and the pad capacitor (C_{pad}) become identical due to charge sharing. By repeating the above operations, the voltage of the external capacitor (Cₑₓₜ) decreases stepwise, and a decrease gradient of the voltage is near linear similarly to the example embodiment 2. Supposing no leakage currents in the circuit, actual operation becomes more similar to computed results, and represents a bisymmetrical waveform.

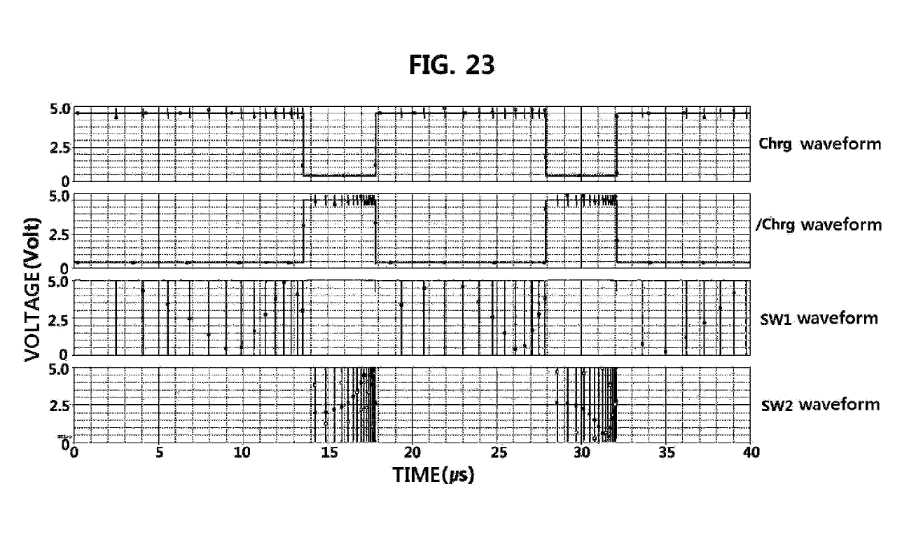

FIGS. 22 and 23 represent output waveforms of a comparing part and a charging/discharging control circuit in connection with the results of FIG. 21. FIG. 22 illustrates output waveforms of the comparing part 1420, output waveforms of the comparator 1, the comparator 2, the comparator 3, and the comparator 4, in sequence. FIG. 23 illustrates output waves of the charging/discharging control circuit 1430, Chrg, /Chrg. SW1, and SW2, in sequence from the upper most. These results have waveforms identical to the above logic table.

Measuring Electrostatic Capacity Using a Multi-Mode Current Charging/Discharging Circuit

All of the rest parts except the pad capacitor are located in an external measuring circuit so that specification of the circuit may be changed according to its use. According to the previous equations, when the charging/discharging and charge sharing method according to the example embodiments of the present invention is used, design parameters related to the measurement on electrostatic capacity are C_{pad}, Cₑₓₜ, and a charging/discharging current (I). Among these, C_{pad} is an independent variable varying according to whether a human body touches or not, and Cₑₓₜ and the charging/discharging current (I) are a control variable to be determined when the circuit for measuring is designed. Therefore, adjustment of Cₑₓₜ and the size of the charging/discharging current (I) can configure the multi-mode measuring circuit. As the charging/discharging current (I) increases, a charging/discharging speed increase so that a time for a cycle may decrease. Also, as Cₑₓₜ increases, an amount of voltage change decreases so that the charging/discharging speed may decrease. By using the above characteristic, a small-current low-speed mode operating with a small charging/discharging current (I) and a small Cₑₓₜ and a large-current high-speed mode operating with a large charging/discharging current (I) and a large Cₑₓₜ can be made.

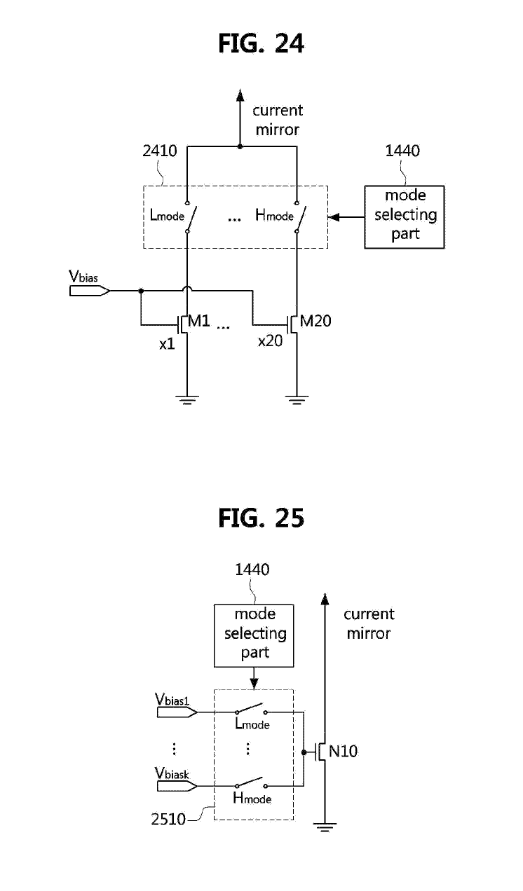

FIGS. 24 and 25 illustrate an example of a static current source circuit for changing a charging/discharging current according to a mode. Since a current flowing through is a channel of transistor is proportional to a bandwidth of the channel, as shown in FIG. 14, NMOS transistors M1 to M20 to which the bias voltage is applied may be configured with NMOS transistors having different channel bandwidths and a mode selecting switch 2140, and so the charging/discharging current can be changed in accordance with a mode.

Also, since the current varies according to a gate bias voltage, as shown in FIG. 25, change of the charging/discharging current according to a mode may be made possible by using different bias voltage terminals and a mode selecting switch 2510.

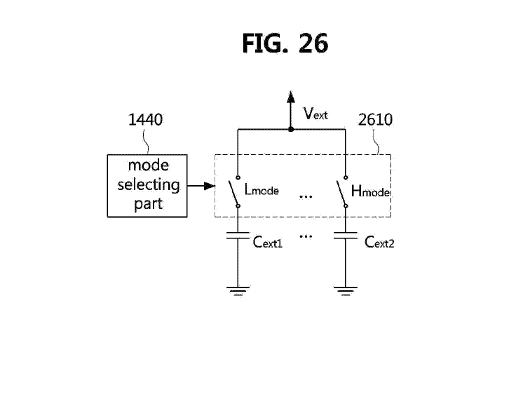

FIG. 26 illustrates an example of a circuit for changing a capacitance of the external capacitor (Cₑₓₜ). Similarly to the case of the static current source, the circuit for changing the capacitance may be configured with a plurality of external capacitors having different capacitances and a mode selecting switch 2610.

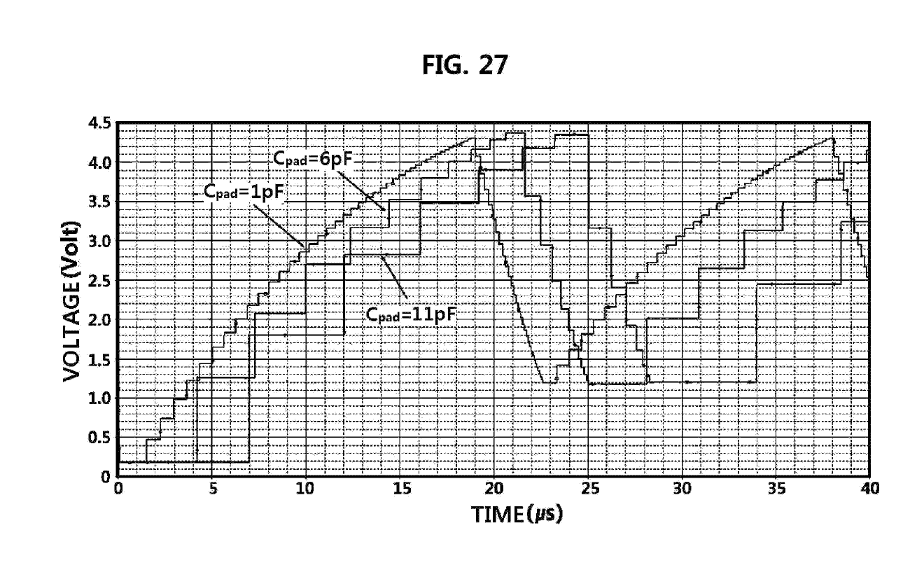

FIG. 27 is a graph illustrating change of Cₑₓₜ according to change of C_{pad} in a circuit operating in a small-current low-speed mode. When a human body does not touch the pad, the value of C_{pad} is low. When a human body touches the pad, the C_{pad} varies from several pF to several tens of pF according to size of touched area. Cₑₓₜ is 20 pF, and the charging/discharging current (I) is about 17 μA, a relatively small current as compared to the case of a large-current high-speed mode. However, it is a relatively large current as compared to that of the conventional charging/discharging method using a current source. The results (time is for completing a first cycle after initial reset) when C_{pad} is 1 pF, 6 pF, and 11 pF respectively are 22.5 μs for 1 pF, 25 μs for 6 pF, and 27.5 μs for 11 pF. Therefore, measurement on a time for completing one or more cycles makes it possible to measure electrostatic capacity due to a touch. The electrostatic capacity due to a touch can also be measured by measuring Vₑₓₜ after 35 μs elapses after the initial reset.

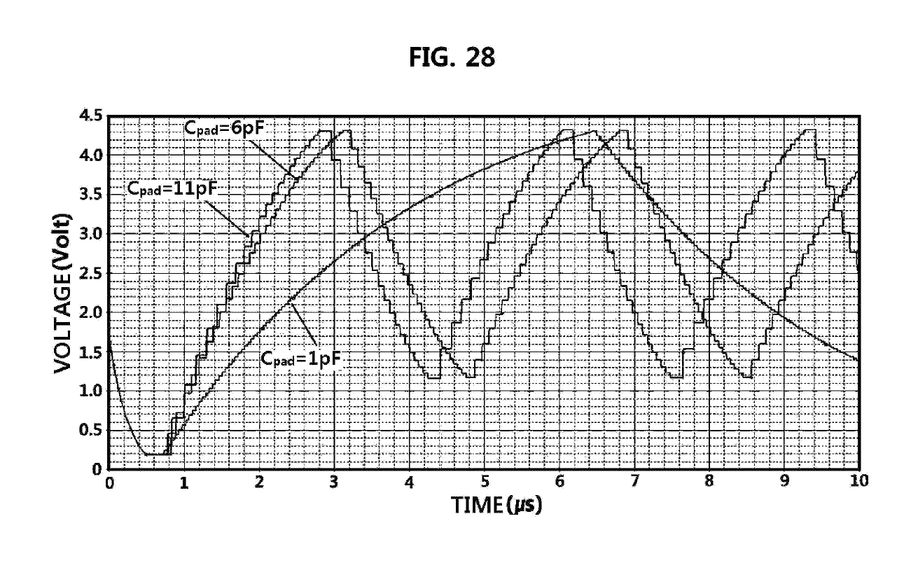

FIG. 28 is a graph illustrating change of Cₑₓₜ according to change of C_{pad} in a circuit operating in a large-current high-speed mode. Cₑₓₜ is 100 pF, and the charging/discharging current (I) is about 370 μA, a relatively large current as compared to that of the conventional charging/discharging method. Therefore, the problem caused by lack of measuring time may be resolved. The results (time for completing a first cycle after initial reset) when C_{pad} is 1 pF, 6 pF, and 11 pF respectively are 10.5 μs for 1 pF, 4.8 μs for 6 pF, and 4.3 μs for 11 pF. The interesting fact of this mode is that the results opposite to those of the small-current low-speed mode are presented due to the large amount of current. That is, the time decreases rather than increases as C_{pad} increases. The time for performing charging/discharging and charge sharing is shortened due to the large amount of current, and the time is caused by a switching delay of the feedback circuit. Since a smaller C_{pad} makes the time for charging and discharging C_{pad} shorter, the speed for charging and discharging Cₑₓₜ is saturated by the switching delay. Therefore, if the charging/discharging current and Cₑₓₜ are configured appropriately, the electrostatic capacity may be measured with a large margin of measurement in a short period as compared to the conventional charging/discharging methods using voltage or current. The various size of current and Cₑₓₜ according to mode selection can be applied to the present invention without being restricted by the example embodiments in this specification.

While the example embodiments of the present invention and their advantages have been described in detail, it should be understood that various changes, substitutions and alterations may be made herein without departing from the scope of the invention.

1. A circuit for measuring electrostatic capacity using a current source, including an external capacitor and at least one pad capacitor, the circuit comprising:
a charging/discharging part for charging or discharging the at least one pad capacitor by using a static current source; and
a charge sharing switching part for controlling charge sharing between the charged or discharged at least one pad capacitor and the external capacitor.

2. The circuit of claim 1, wherein the charging/discharging part comprises:
a static current source providing a static current; and
a charging/discharging control switch for controlling a charging switch or a discharging switch to charge or discharge the at least one pad capacitor selectively by using the static current.

3. The circuit of claim 2, wherein the charging/discharging part controls charging operation or discharging operation on the at least one pad capacitor by comparing voltages of the at least one pad capacitor and a voltage of the external capacitor with a reference voltage.

4. The circuit of claim 3, wherein the charging/discharging part activates a charging control signal (SW1) for performing the charging operation by turning the charging switch on when the voltage of the at least one pad capacitor is lower than a first reference voltage and the voltage of the external capacitor is lower than a second reference voltage.

5. The circuit of claim 4, wherein the charge sharing control part performs the charge sharing when the voltage of the pad capacitor is lower than the first reference voltage and the voltage of the external capacitor is lower than the second reference voltage and the charging control signal (SW1) is deactivated.

6. The circuit of claim 3, wherein the charging/discharging part activates a discharging control signal (SW2) for performing the discharging operation by turning the discharging switch on when the voltage of the external capacitor is higher than a third reference voltage and the voltage of the pad capacitor is lower than a fourth reference voltage.

7. The circuit of claim 6, wherein the charge sharing control part performs the charge sharing when the voltage of the pad capacitor is lower than the fourth reference voltage and the voltage of the external capacitor is higher than the third reference voltage and the discharging control signal (SW2) is deactivated.

8. The circuit of claim 3, wherein the charging/discharging part activates a charging control signal (SW1) for performing the charging operation by turning the charging switch on when the voltage of the at least one pad capacitor is lower than a first reference voltage and the voltage of the external capacitor is lower than a third reference voltage.

9. The circuit of claim 8, wherein the charging/discharging part activates a discharging control signal (SW2) for performing the discharging operation by turning the discharging switch on when the voltage of the at least one pad capacitor is lower than a fourth reference voltage and the voltage of the external capacitor is higher than a second reference voltage.

10. The circuit of claim 9, wherein the charge sharing control part perform the charge sharing by operating oppositely to the charging switch in a charging period and operating oppositely to the discharging switch in a discharging period.

11. The circuit of claim 1, further comprising a multiplexor selecting at least one of a plurality of touch pad electrodes.

12. The circuit of claim 1, further comprising:
a reference voltage generating circuit generating at least one reference voltage and a plurality of bias voltages;
a comparing part generating at least one logic control signal by comparing the voltage of the at least one pad capacitor and the voltage of the external capacitor with the at least one reference voltage; and
a charging/discharging control circuit controlling operations of the charging/discharging part by using the at least one logic control signal.

13. The circuit of claim 12, further comprising:
a data processing part measuring electrostatic capacity using outputs of the comparing part and the voltage of the external capacitor; and
a mode selecting part controlling an amount of the current for charging or discharging and capacitance of the external capacitor.

14. The circuit of claim 13, wherein the mode selecting pat changes the amount of the current of the static current source and the capacitance of the external capacitor in order to implement a plurality of modes.

15. The circuit of claim 1, wherein the charge sharing part charges or discharges the external capacitor by performing charge sharing between the at least one pad capacitor and the external capacitor repetitively.

16. The circuit of claim 1, wherein the electrostatic capacity is measured using the voltage of the external capacitor and a charging time or discharging time for the at least one pad capacitor.

17. The circuit of claim 1, wherein the electrostatic capacity is measured by measuring a time required for charging the pad capacitor to a reference voltage or discharging the pad capacitor.

18. A method for measuring electrostatic capacity using a circuit for measuring electrostatic capacity using a current source, including an external capacitor and at least one pad capacitor, the method comprising:
charging or discharging the at least one pad capacitor by using a static current source; and
performing charge sharing between the charged or discharged at least one pad capacitor and the external capacitor.

19. The method of claim 18, wherein, in the performing charge sharing, the external capacitor is charged or discharged by repetitively performing the charge sharing between the charged or discharged at least one pad capacitor and the external capacitor.

20. The method of claim 18, further comprising measuring electrostatic capacity by using a voltage of the external capacitor and a time required for charging or discharging the at least one pad capacitor.
